(19) United States
(12) Patent Application Publication
(10) Pub. No.: US 2025/0315172 A1
(43) Pub. Date: Oct. 9, 2025

(54) Input-Aware Data Inversion Scheme for Low Power Memory Circuit Design

(71) Applicant: Taiwan Semiconductor Manufacturing Company, Ltd., Hsinchu (TW)

(72) Inventors: Je-Min Hung, Hsinchu City (TW); Haruki Mori, Hsinchu City (TW); Hidehiro Fujiwara, Hsinchu City (TW); Yen-Huei Chen, Hsinchu City (TW)

(73) Assignee: Taiwan Semiconductor Manufacturing Company, Ltd., Hsinchu (TW)

(21) Appl. No.: 18/626,116

(22) Filed: Apr. 3, 2024

(51) Int. Cl. G06F 3/06

(52) U.S. Cl. CPC G06F 3/0625; G06F 3/0659; G06F 3/0673

(57) ABSTRACT

A memory circuit may comprise a memory array, a data pattern detector, and a write driver. The memory array may comprise a plurality of memory bit cells. The data pattern detector can be configured to: (i) receive a plurality of data bits; (ii) identify a first number of a first subset of the data bits that are each equal to a first logic state and a second number of a second subset of the data bits that are each equal to a second logic state; and (iii) selectively adjust respective logic states of the data bits based on comparing the first number with the second number. The write driver can be configured to write the selectively adjusted logic states of the data bits into the plurality of memory bit cells, respectively.

### BACKGROUND

Memory devices are integral components of electronic systems, storing data in a manner that allows for rapid access and modification. Traditionally, memory devices have been designed to store binary information in the form of “0”s and “1”s across a vast array of memory cells. These cells, due to manufacturing variances and design constraints, often exhibit unbalanced physical structures, leading to disparities in their electrical characteristics. One such characteristic is leakage current, which represents the flow of electrical current within a memory cell when it is not being actively accessed or modified.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory circuit 100, in accordance with some embodiments of the present disclosure.

FIG. 2 illustrates a detailed schematic diagram of the memory circuit 100 of FIG. 1, in accordance with some embodiments of the present disclosure.

FIG. 3 illustrates an example detailed schematic diagram of the data pattern detector 130 of FIG. 1, in accordance with some embodiments of the present disclosure.

FIG. 4 illustrates an example performance evaluation of the memory circuit 100 of FIG. 1, in accordance with some embodiments of the present disclosure.

FIG. 5 is a flowchart of an example method for operating the memory circuit 100 of FIGS. 1 and 2, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In conventional memory systems, data is directly stored into the memory cell array without considering the pattern of the data. For instance, if the data to be written is “00011000” or “11101001”, it is written as is into the memory cell array. Traditional methods aimed at low power design have primarily focused on adjusting the threshold voltage (VT) or modulating the supply voltage (VDD). However, these methods do not account for specific data patterns that can influence power consumption. For example, in certain neural network layers, there is a prevalence of negative weights, represented by binary patterns such as “1111XXXX” or “11111XXX.” These patterns, when frequently accessed or modified, lead to substantial energy usage during read and write operations, highlighting the need for a more data-pattern-aware approach to power management in memory design.

The present disclosure relates to memory devices and, more particularly, to a system and method for addressing energy consumption during read/write operation in memory devices to achieve low power consumption. Unbalanced cell structures in the memory devices can lead to variances in the energy required to read from or write to the memory cells. This discrepancy further contributes to inefficiencies, as the power consumption for writing a “0” may differ from that for writing a “1”, and similarly for read operations. Such differences in power consumption can be particularly problematic in low power applications where energy efficiency is paramount. Previous approaches to designing low power memory devices have largely overlooked these variances in cell structure and their impact on power consumption. Consequently, there exists a need for a memory design methodology that takes into account the energy consumption during read/write operation to minimize power consumption during both read and write operations.

The present disclosure provides various embodiments of a memory circuit that address such issues. For example, the memory circuit, as disclosed herein, includes a memory array, a data pattern detector, and a write driver. The data pattern detector can detect a data pattern before the data is stored. If, for instance, the power consumption for standby, reading, or writing a “1” is greater than for a “0”, the data pattern detector assesses the data: should the count of “1”s exceed the “0”s, the data pattern detector inverts the data (e.g., from “1111_0011_1110 0101” to “0000 1100_0001_1010”) and sets an inversion flag (e.g., INV_FLAG) to 1.

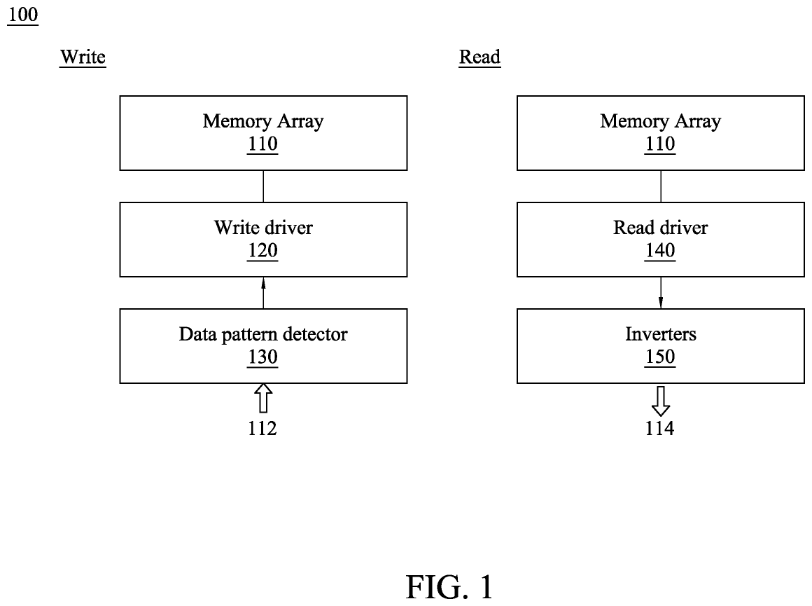

FIG. 1 illustrates a block diagram of a memory circuit 100, in accordance with some embodiments of the present disclosure. The memory circuit 100 may include a memory array 110, a writer driver 120, and a data pattern detector 130. In some embodiments, the memory circuit 100 may include a memory array 110, a read driver 140, and a plurality of inverters 150.

The memory array 110 may comprise a plurality of memory bit cells. One or more peripheral circuits (not shown) may be located at one or more regions peripheral to, or within, the memory array 110. The memory bit cells and the periphery circuits may be coupled by word lines and/or complementary bit lines BL and BLB, and data can read from and written to the memory bit cells via the complementary bit lines BL and BLB. Different voltage combinations applied to the word lines and bit lines may define a read, erase or write (program) operation on the memory bit cells. In some embodiments, the memory array 110 architecture can incorporate various types of non-volatile or volatile memory technologies, including but not limited to static random-access memory (SRAM), resistive random-access memory (ReRAM), magnetoresistive random-access memory (MRAM), and phase-change random access memory (PCRAM). The proposed low-power memory circuit design is versatile and can be adapted to enhance the power efficiency of all kinds of memory technologies, addressing the universal challenge of energy consumption in diverse memory systems.

In some embodiments, the data pattern detector 130 may detect data pattern (represented by open arrow 112) before writing data into the memory cell array 110. The data pattern detector 130 can be configured to receive a plurality of data bits (represented by open arrow 112). For example, the data pattern detector 130 may receive one or more 16-bit data strings. Example of such 16-bit data strings can be “1100_0000_1100_0101” or “1111 0011_1110_0101.” In some embodiments, the data pattern detector 130 may include a counter that comprises a plurality of adders and at least one comparator.

In some embodiments, the data pattern detector 130 can be further configured to identify a first number of a first subset of the data bits that are each equal to a first logic state (e.g., a logic “1”) and a second number of a second subset of the data bits that are each equal to a second logic state (e.g., a logic “0”). For example, the first logic state can be a logic 1 and the second logic state can be a logic 0. In certain embodiments, the data pattern detector 130 can be designed to identify the data pattern prior to the initiation of the write process into the memory cell array 110, as indicated by the open arrow 112. The data pattern detector 130 can be adept at handling multiple bits simultaneously; for instance, it is capable of processing the 16-bit data strings (e.g., “1100_0000_1100_0101” or “1111_0011_1110_0101”), among others. By examining these patterns, the memory circuit can make informed decisions on how to store data efficiently and with reduced energy consumption.

In some embodiments, the data pattern detector 130 can be further configured to determine the first number (e.g., equipped to ascertain the count of the initial logic “1” values in a given data string). For instance, the data pattern detector 130 is capable of determining that the number of logic “1”s (e.g., the first number) is 6 within the data string “1100_0000_1100_0101.” In a different scenario, the data pattern detector 130 may identify that the first number is 11 for the data string “1111_0011_1110_0101.” Moreover, the data pattern detector 130 has the functionality to compare the first number against a threshold value. The data pattern detector 130 can be further configured to determine the threshold value as one half (e.g., 8) of a total number of the data bits (e.g., 16). The threshold can be defined as half the total bit count of the data string; for example, it can be 8 for a 16-bit data string. In certain embodiments, the threshold value may be preset/preconfigured to a half-value relative to the total bit count of the data strings being analyzed (e.g., one half of a total number of data bits). In some embodiments, the inverting threshold is adjustable.

In some embodiments, the data pattern detector 130 can be further configured to selectively adjust respective logic states of the data bits based on comparing the first number with the second number. In some embodiments, since storing/reading/programming data “1” has larger readout/write energy consumption, the data pattern detector 130 may selectively adjust respective logic states of the data bits when the number of logic 1 is larger than the number of logic 0. The data pattern detector 130 may invert the data before writing the memory cell array 110 if the number of logic “1” larger than the number of logic “0.” For example, the number of logic “1”s (e.g., the first number) is 11 and the number of logic “0”'s (e.g., the second number) is 5 within the data string “1111_0011_1110_0101.” In such case, the number of logic “1” (e.g., the first number) is larger than the number of logic “0” (e.g., the second number). In response to the first number being larger than the second number, the data pattern detector 130 may logically invert respective logic states of the data string “1111_0011 1110 0101” to “0000_1100_0001 1010.”

In some embodiments, the data pattern detector 130 can be further configured to, in response to the first number being larger than the threshold value, logically inverse the respective logic states of the data bits. For example, the number of logic “1”s (e.g., the first number) is 11 and the threshold value (e.g., one half of a total number of data bits) is 8 for the data string “1111 0011 1110_0101.” In such case, the number of logic “1” (e.g., 11) is larger than the threshold value (e.g., 8). In response to the first number being larger than the threshold value, the data pattern detector 130 may logically invert respective logic states of the data string “1111_0011_1110_0101” to “0000_1100_0001_1010.” In certain embodiments, the threshold value is preconfigured as one half of a total number of the data bits. In some embodiments, the data pattern detector 130 can be further configured to provide a flag bit (e.g., INV_Flag) indicating whether the first number is larger than (or equal to or less than) the threshold value. The flag bit can be equal to a first value (e.g., 1) when the first number is larger than the threshold value. The flag bit can be equal to a second value (e.g., 0) when the first number is equal to or less than the threshold value. In certain embodiments, the data pattern detector 130 can be further configured to provide a flag bit indicating whether the first number is larger than (or equal to or less than) the second number. The flag bit can be equal to a first value (e.g., 1) when the first number is larger than the second number. The flag bit can be equal to a second value (e.g., 0) when the first number is equal to or less than the second number. For example, the flag bit can be 1 (e.g., INV_Flag=1) for the inverted data string “0000_1100_0001_1010.” Addition flag storage and counter may be needed. The bit width of the data string for detection can be adjustable. The write driver 120 can be configured to write the selectively adjusted logic states of the data bits (e.g., “0000_1100_0001_1010”) and the flag bit (e.g., INV_Flag=1) into the plurality of memory bit cells 110.

In some embodiments, the data pattern detector 130 can be further configured to, in response to the first number being less than or equal to the threshold value, logically maintain the respective logic states of the data bits. For example, the number of logic “1”s (e.g., the first number) is 6 and the number of logic “0”'s (e.g., the second number) is 10 within the data string “1100 0000_1100_0101.” In such case, the number of logic “1” (e.g., the first number) is less than the number of logic “0” (e.g., the second number). In response to the first number being less than the second number, the data pattern detector 130 may logically maintain/sustain the respective logic states of the data string of “1100_0000_1100_0101.” In some embodiments, the data pattern detector 130 can be further configured to provide a flag bit (e.g., INV_Flag) indicating whether the first number is larger than (or equal to or less than) the threshold value. The flag bit can be equal to a first value (e.g., 1) when the first number is larger than the threshold value. The flag bit can be equal to a second value (e.g., 0) when the first number is equal to or less than the threshold value. In certain embodiments, the data pattern detector 130 can be further configured to provide a flag bit indicating whether the first number is larger than (or equal to or less than) the second number. The flag bit can be equal to a first value (e.g., 1) when the first number is larger than the second number. The flag bit can be equal to a second value (e.g., 0) when the first number is equal to or less than the second number. For example, the flag bit can be 0 (e.g., INV_Flag=0) for the maintained/sustained data string “1100_0000_1100_0101.” Addition flag storage and counter may be needed. The bit width of the data string for detection can be adjustable. The write driver 120 can be configured to write the maintained/sustained logic states of the data bits (e.g., “1100_0000_1100_0101”) and the flag bit (e.g., INV_Flag=0) into the plurality of memory bit cells 110.

In some embodiments, the read driver 140 can be configured to read, from the memory bit cells 110, the logic states of the data bits and/or the flag bit (e.g., INV_Flag). For example, the read driver 140 may read the logic states of data string of “0000_1100_0001_1010” and the flag bit of INV_Flag=1. In another example, the read driver 140 may read the logic states of data string of “1100_0000_1100_0101” and the flag bit of INV_Flag=0. The flag bit may indicate that the first number is larger than the threshold value when the flag bit is equal to a first value (e.g., 1). The flag bit may indicate that the first number is equal to or less than the threshold value when the flag bit is equal to a second value (e.g., 0).

The plurality of inverters 150 can be configured to selectively logically invert the read logic states based on the flag bit (e.g., INV_Flag). In some embodiments, the plurality of inverters 150 can be activated in response to the flag bit being equal to the first value (e.g., 1), and/or may remain deactivated in response to the flag bit being equal to the second value (e.g., 0). For example, the read driver 140 may read the logic states of data string of “0000_1100_0001_1010” and the flag bit of INV_Flag=1. In response to the flag bit being equal to 1, the plurality of inverters 150 may logically invert the read logic states of the data string of “0000_1100_0001_1010” to “1111_0011_1110_0101.” For another example, the read driver 140 may read the logic states of data string of “1100_0000_1100_0101” and the flag bit of INV_Flag=0. In response to the flag bit being equal to 0, the plurality of inverters 150 may remain deactivated without logically inverting the read logic states of the data string of “1100_0000_1100_0101.”

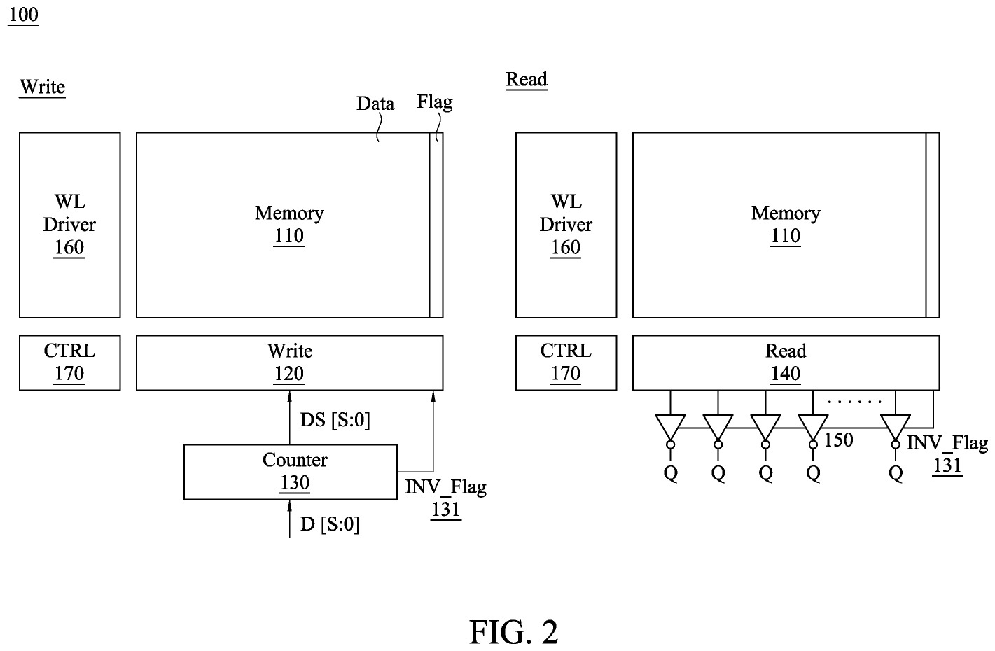

FIG. 2 illustrates a detailed schematic diagram of the memory circuit 100 of FIG. 1, in accordance with some embodiments of the present disclosure. The memory circuit 100 may include a memory array 110, a writer driver 120, a data pattern detector 130, a control circuit 170, and a word line (WL) driver 160. In some embodiments, the memory circuit 100 may include a memory array 110, a read driver 140, a plurality of inverters 150, a control circuit 170, and a word line (WL) driver 160. The memory circuit 100 of FIG. 2 is substantially similar to the memory device 100 of FIG. 1. The specific operations of similar elements, which are already discussed in detail in above paragraphs, are omitted herein for the sake of brevity, unless there is a need to introduce the co-operation relationship with the elements shown in FIG. 2.

In a write mode, the data pattern detector 130 may receive a plurality of data bits (e.g., D [S:0]). The data pattern detector 130 may identify a first number of a first subset of a plurality of data bits that are each equal to a first logic state (e.g., 1) being larger than a second number of a second subset of the data bits that are each equal to a second logic state (e.g., 0). In certain embodiments, the data pattern detector 130 may identify a first number of a first subset of a plurality of data bits that are each equal to a first logic state (e.g., 1) being larger than a threshold value. In such case, the data pattern detector 130 may logically invert respective logic states of the data bits (e.g., DS [S:0]) and provide a flag bit (e.g., INV_Flag) 131. The write driver 120 can be configured to write the logically inverted logic states of the data bits (e.g., DS [S:0]) and the flag bit (e.g., INV_Flag=1) 131 into the plurality of memory bit cells 110, respectively. In some embodiments, the data pattern detector 130 may identify a first number of a first subset of a plurality of data bits that are each equal to a first logic state (e.g., 1) being less than a threshold value. In such case, the data pattern detector 130 may sustain respective logic states of the data bits (e.g., DS [S:0]) and provide a flag bit (e.g., INV_Flag=0) 131. The write driver 120 can be configured to write the logically sustained logic states of the data bits (e.g., DS [S:0]) and the flag bit (e.g., INV_Flag=0) 131 into the plurality of memory bit cells 110, respectively.

In a read mode, the read driver 140 can be configured to read, from the memory bit cells 110, the logic states of the data bits and the flag bit (e.g., INV_Flag) 131. For example, the read driver 140 may read the logic states of data string of “0000_1100_0001_1010” and the flag bit 131 of INV_Flag=1. In response to the flag bit 131 being equal to 1, the plurality of inverters 150 may logically invert the read logic states of the data string of “0000_1100_0001_1010” to “1111_0011_1110_0101.” For another example, the read driver 140 may read the logic states of data string of “1100_0000_1100_0101” and the flag bit of INV_Flag=0. In response to the flag bit 131 being equal to 0, the plurality of inverters 150 may remain deactivated without logically inverting the read logic states of the data string of “1100_0000_1100_0101.”

The control circuit 170 may capture data from a temporary storage source through the complementary DLB and DL inputs. These input signals may control the transistor columns, influencing BL and BLB voltages, which are converted to binary signals for control circuit. In this configuration, a write-in latch can hold the DL data during a clock cycle for writing into memory cells. During a read operation, the write-in latch is largely inactive. This configuration facilitates writing operations based on inputs, enabling data storage in corresponding locations.

The word line (WL) driver 160 can be responsible for activating the word lines within the memory array 110. When data needs to be read from or written to a row of memory cells 110, the word line (WL) driver 160 may select the appropriate word line by driving it to a higher voltage level. The selected row of cells can then be read from or written to by sense amplifiers or write drivers connected to the bit lines, which run vertically and intersect with the word lines.

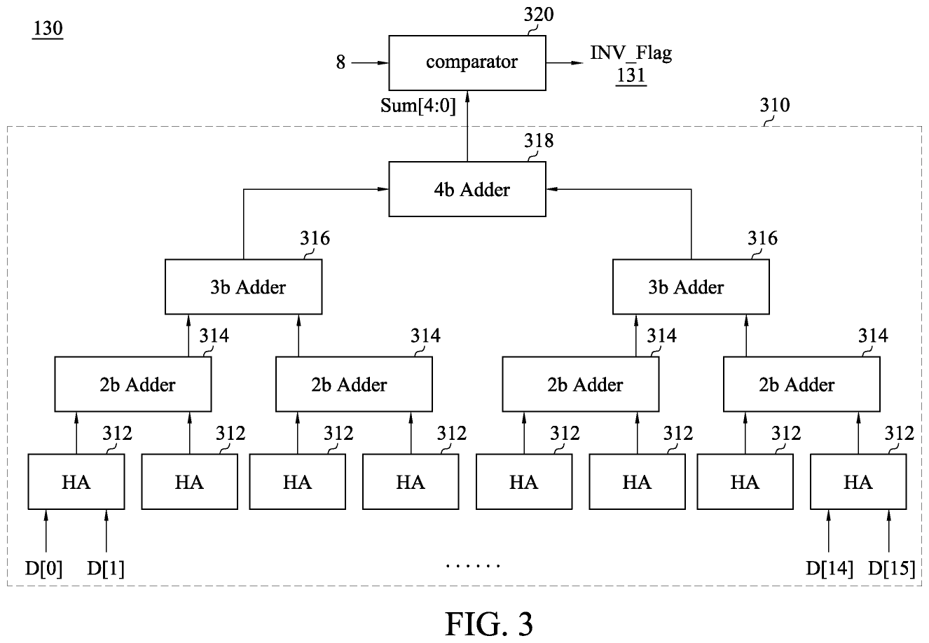

FIG. 3 illustrates an example detailed schematic diagram of the data pattern detector 130 of FIG. 1, in accordance with some embodiments of the present disclosure. The data pattern detector 130 may include a counter 310 and at least one comparator 320.

The counter 310 may comprise a plurality of adders, in some embodiments. For example in FIG. 3, the counter 310 includes a plurality of first adders 312, a plurality of second adders 314, a plurality of third adders 316, and a plurality of fourth adders 318. The first adders 312 may be arranged in a first level to receive a data string (e.g., a 16-bit data string: D[0], D[1], . . . , D[14], and D[15]). The second adders 314 may be arranged in a second level to receive outputs from the first level. The third adders 316 may be arranged in a third level to receive outputs from the second level. The fourth adders 318 may be arranged in a fourth level to receive outputs from the third level. The second adders 314, the third adders 316, and the fourth adders 318 may comprises a plurality of full adders. In various embodiments, a second adder 314 may be connected with two first adders 312. As a non-limiting example, such an arrangement may

be implemented for a 16-bit data string (e.g., D[0], D[1], . . . , D[14], and D[15]) of various embodiments. For example, for a data string of “1110_1011_0110_1101, D[0]=1, D[1]=1, D[2]=1, D[3]=0, D[4]=1, D[5]=0, D[6]=1, D[7]=1, D[8]=0, D[9]=1, D[10]=1, D[11]=0, D[12]=1, D[13]=1, D[14]=0, and D[15]=1. In FIG. 3, the first adder 312 on the most left side may receive input from D[0] and D[1], and may output a result of 2 to the second adder 314. The first adder 312 on the most right side may receive input from D[14] and D[15], and may output a result of 1 to the second adder 314. For the data string of “1110_1011_0110_1101,” the fourth adders 318 may output a result of 11 to the comparator 320. Nevertheless, it should be appreciated that the number of the half adders and/or the number of the full adders provided may depend on the size of the data string. The plurality of adders 312, 314, 316, 318 may generate a result (e.g., Sum [4:0]) for the data string to the comparator 320.

The comparator 320 can be configured to provide an output (e.g., INV_Flag) 131 based on the result (e.g., Sum [4:0]) of the adders 312, 314, 316, 318 and a threshold value (e.g., 8).

The comparator 320 can be employed to assess the sum of a specified subset of bits within a 16-bit data width, denoted as D[15:0]. The focus of this evaluation is on the result (e.g., Sum[4:0]) from the adders 312, 314, 316, 318. When the result of the data string exceeds the value of 8, a flag bit (e.g., INV_Flag) is set to 1. For the data string of “1110_1011_0110_1101,” the result of the data string from the adders is 11, which exceeds the threshold value of 8. The comparator 320 set the flag bit to 1. This flag bit signals the system to invert the entire 16-bit data string (e.g., from “1110_1011_0110_1101” to “0001 0100_1001_0010”), effectively toggling each bit's value. Conversely, if the result of the data string is less than or equal to 8, the INV_Flag is set to 0, indicating that the data should remain in its original state without any inversion. This conditional flagging allows for dynamic data manipulation based on the predefined threshold, optimizing the data for processes that may benefit from such inversion, such as power reduction or data integrity enhancement in memory storage operations.

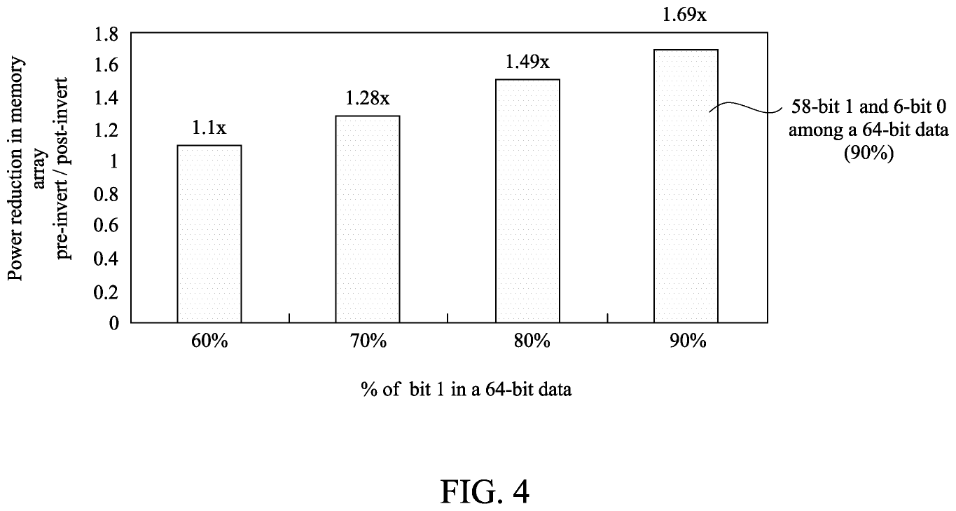

FIG. 4 illustrates an example performance evaluation of the memory circuit 100 of FIG. 1, in accordance with some embodiments of the present disclosure. As shown in FIG. 4, the efficacy of this disclosure is directly proportional to the quantity of “1” bits present in the data string. In some embodiments, storing/reading/programming data “1” has larger readout/write energy consumption. The relationship in FIG. 4 is underscored by the assumed current ratio for reading and writing “0” and “1” states, which stands at 2. Specifically, as the percentage of “1” bits in the data increases, from a threshold of 60% up to 90%, the low power memory circuit design of this disclosure is capable of achieving a corresponding increment in power reduction efficiency. This improvement in power efficiency ranges from 1.1 times to as much as 1.69 times, providing substantial energy savings. It should be noted that this estimation of power reduction does not take into account the additional circuitry that may be required, such as an accumulator for summing the “1” bits or storage for the inversion flag. These additional components are essential for the operation of the system but are excluded from the power reduction estimation provided.

In the pursuit of low power design for memory systems, several strategies can be employed to minimize energy consumption. Adjusting the threshold voltage (VT) is one method, which involves calibrating the voltage at which a transistor switches from off to on, thus controlling the power usage during the transistor's active and standby modes. Another approach is to fine-tune the supply voltage (VDD), where reducing the voltage can lead to significant power savings, albeit at a potential trade-off with performance due to slower transistor switching speeds. Beyond hardware-level adjustments, data compression techniques can be integrated to enhance storage efficiency; for instance, run-length encoding and Huffman encoding are methods that can reduce the amount of data to be written to and read from the memory, thereby decreasing the overall power required for these operations. These data compression schemes are particularly effective because they decrease the number of memory accesses, which are often the primary consumers of power in memory systems.

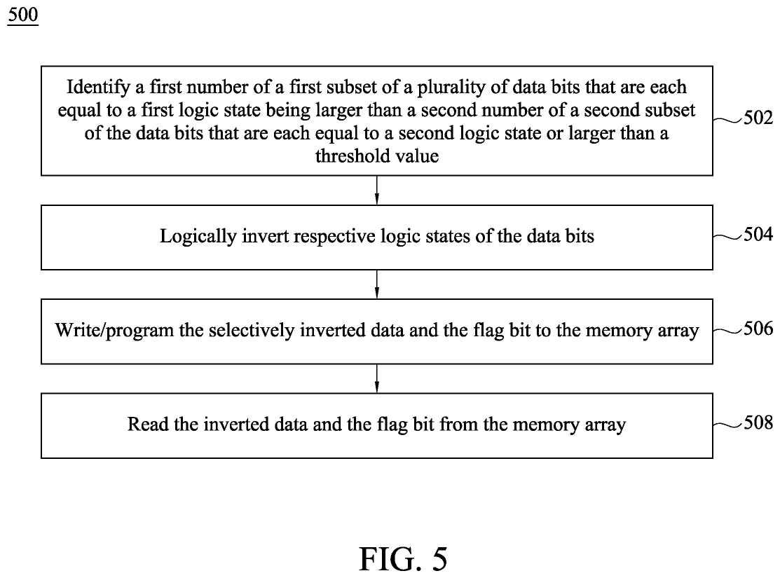

FIG. 5 is a flowchart of an example method 500 for operating the memory circuit 100 of FIGS. 1 and 2, in accordance with some embodiments of the present disclosure. The method 500 may be used to operate the memory circuit 100. For example, at least some of the operations described in the method 500 can be performed during a write mode or a read mode for a memory circuit 100. It is noted that the method 500 is merely an example and is not intended to limit the present disclosure. Accordingly, it is understood that additional operations may be provided before, during, and after the method 500 of FIG. 5, and that some other operations may only be briefly described herein.

The method 500 starts with an operation in which a memory circuit 100 may receive a plurality of data bits. The method 500 continues to operation 502 in which a memory circuit 100 may identify a first number of a first subset of a plurality of data bits (e.g., D [S:0]) that are each equal to a first logic state (e.g., “1”) being larger than a second number of a second subset of the data bits (e.g., D [S:0]) that are each equal to a second logic state (e.g., “0”) or larger than a threshold value (e.g., “8”). The first logic state is a logic 1 and the second logic state is a logic 0. In certain embodiments, the method 500 continues to an operation in which the memory circuit 100 may identify a first number of a first subset of a plurality of data bits (e.g., D [S:0]) that are each equal to a first logic state (e.g., “1”) being equal to or less than a second number of a second subset of the data bits (e.g., D [S:0]) that are each equal to a second logic state (e.g., “0”), or equal to or less than a threshold value (e.g., “8”).

The method 500 continues to operation 504 in which the memory circuit 100 may logically inverting respective logic states of the data bits. For example, the number of logic “1”s (e.g., the first number) is 11 and the threshold value (e.g., one half of a total number of data bits) is 8 for the data string “1111_0011_1110_0101.” In such case, the number of logic “1” (e.g., 11) is larger than the threshold value (e.g., 8). In response to the first number being larger than the threshold value, the data pattern detector 130 may logically invert respective logic states of the data string “1111_0011_1110_0101” to “0000_1100_0001_1010.” In certain embodiments, the method 500 continues to an operation in which the memory circuit 100 may sustain respective logic states of the data bits when the first number is equal to or less than the second number, or equal to or less than the threshold value.

The method 500 continues to an operation in which the memory circuit 100 may provide a flag bit 131 indicating whether the first number is larger or less than the threshold value. For example, the flag bit can be 1 (e.g., INV_Flag=1) for the inverted data string “0000 1100 0001_1010.” Addition flag storage and counter may be needed. The bit width of the data string for detection can be adjustable. The write driver 120 can be configured to write the selectively adjusted logic states of the data bits (e.g., “0000_1100_0001_1010”) and the flag bit (e.g., INV_Flag=1) into the plurality of memory bit cells 110. In certain embodiments, if the first number is equal to or less than the second number, or equal to or less than the threshold value, the flag bit can be 0 (e.g., INV_Flag=0) for the sustained data string.

The method 500 continues to operation 506 in which the memory circuit 100 may write/program the selectively inverted or sustained data and the flag bit to the memory array 110. In some embodiments, the method 500 continues to operation 508 in which the memory circuit 100 may read the inverted or sustained data and the flag bit from the memory array 110. The method 500 continues to an operation in which the memory circuit 100 may selectively logically invert the read logic states based on the flag bit (e.g., INV_Flag).

The present disclosure provides a memory macro that is designed with sophisticated features to optimize power consumption based on data patterns. The first feature involves detecting the data pattern before the data is stored. If, for instance, the overhead for standby, reading, or writing a “0” is greater than for a “1”, the memory macro assesses the data: should the count of “0”s exceed the “1”s, the memory macro inverts the data and sets an inversion flag (e.g., INV_FLAG) to 1. Conversely, if “0”s are fewer, the memory macro maintains the data as is, with INV_FLAG set to 0. Conversely, if “1”s have a larger overhead than “0”s, the memory macro inverts the data when “1”s outnumber “0”s, again setting INV_FLAG to 1, or retains the data when “1”s are in the minority, with INV_FLAG remaining at 0. The third feature ensures that after the data is read out, the memory macro can invert the data pattern by adopting the flag bit (e.g., INV_FLAG). This functionality allows for dynamic adaptation to the most energy-efficient data state, reducing power usage during the various operations of the memory macro.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory circuit, comprising:
a memory array comprising a plurality of memory bit cells;
a data pattern detector configured to: (i) receive a plurality of data bits; (ii) identify a first number of a first subset of the data bits that are each equal to a first logic state and a second number of a second subset of the data bits that are each equal to a second logic state; and
(iii) selectively adjust respective logic states of the data bits based on comparing the first number with the second number; and
a write driver configured to write the selectively adjusted logic states of the data bits into the plurality of memory bit cells, respectively.

2. The memory circuit of claim 1, wherein the data pattern detector includes a counter that comprises a plurality of adders and at least one comparator.

3. The memory circuit of claim 1, wherein the first logic state is a logic 1 and the second logic state is a logic 0.

4. The memory circuit of claim 3, wherein the data pattern detector is further configured to: (i) determine the first number; (ii) compare the first number with a threshold value; (iii) in response to the first number being larger than the threshold value, logically inverse the respective logic states of the data bits; and (iv) in response to the first number being less than the threshold value, logically maintain the respective logic states of the data bits.

5. The memory circuit of claim 4, wherein the data pattern detector is further configured to determine the threshold value as one half of a total number of the data bits.

6. The memory circuit of claim 4, wherein the threshold value is preconfigured as one half of a total number of the data bits.

7. The memory circuit of claim 4, wherein the data pattern detector is further configured to provide a flag bit indicating whether the first number is larger or less than the threshold value.

8. The memory circuit of claim 7, further comprising:
a read driver configured to read, from the memory bit cells, the logic states of the data bits; and
a plurality of inverters configured to selectively logically invert the read logic states based on the flag bit.

9. The memory circuit of claim 8, wherein the flag bit is equal to a first value when the first number is larger than the threshold value, and the flag bit is equal to a second value when the first number is less than the threshold value.

10. The memory circuit of claim 9, wherein the plurality of inverters are activated in response to the flag bit being equal to the first value, and remain deactivated in response to the flag bit being equal to the second value.

11. A memory circuit, comprising:
a memory array comprising a plurality of memory bit cells;
a data pattern detector configured to: (i) identify a first number of a first subset of a plurality of data bits that are each equal to a first logic state being larger than a second number of a second subset of the data bits that are each equal to a second logic state or larger than a threshold value; and (ii) logically invert respective logic states of the data bits; and
a write driver configured to write the logically inverted logic states of the data bits into the plurality of memory bit cells, respectively.

12. The memory circuit of claim 11, wherein the data pattern detector includes a counter that comprises a plurality of adders and at least one comparator.

13. The memory circuit of claim 11, wherein the first logic state is a logic 1 and the second logic state is a logic 0.

14. The memory circuit of claim 11, wherein the data pattern detector is further configured to determine the threshold value as one half of a total number of the data bits.

15. The memory circuit of claim 11, wherein the threshold value is preconfigured as one half of a total number of the data bits.

16. The memory circuit of claim 11, wherein the data pattern detector is further configured to provide a flag bit indicating whether the first number is larger or less than the threshold value.

17. The memory circuit of claim 16, further comprising:
a read driver configured to read, from the memory bit cells, the logic states of the data bits; and
a plurality of inverters configured to selectively logically invert the read logic states based on the flag bit.

18. A method for operating a memory circuit, comprising:
identifying a first number of a first subset of a plurality of data bits that are each equal to a first logic state being larger than a second number of a second subset of the data bits that are each equal to a second logic state or larger than a threshold value; and
logically inverting respective logic states of the data bits.

19. The method of claim 18, wherein the first logic state is a logic 1 and the second logic state is a logic 0.

20. The method of claim 18, further comprising:
providing a flag bit indicating whether the first number is larger or less than the threshold value.
